(19) United States
(12) Patent Application Publication
(10) Pub. No.: US 2025/0069655 A1
(43) Pub. Date: Feb. 27, 2025

(54) BIT-SERIAL INPUT SCHEMES FOR CROSSBAR CIRCUITS

(71) Applicant: TetraMem Inc., Fremont, CA (US)

(72) Inventors: Hengfang Zhu, Fremont, CA (US); Wenbo Yin, Alameda, CA (US)

(73) Assignee: TetraMem Inc., Fremont, CA (US)

(21) Appl. No.: 18/456,452

(22) Filed: Aug. 25, 2023

(51) Int. Cl. G11C 13/00

(52) U.S. Cl. CPC G11C 13/0028; G11C 13/0026; G11C 13/004; G11C 13/003; G11C 2213/79

(57) ABSTRACT

According to some aspects of the disclosure, a crossbar circuit may include a plurality of bit lines intersecting with a plurality of word lines, a plurality of cross-point devices, and a plurality of switches connected to the plurality of word lines. Each of the plurality of cross-point devices is connected to at least one of the word lines and at least one of bit lines and may include a resistive random-access memory (RRAM) device. Each of the switches is selectively connected to ground or a reference voltage. A digital input may be provided to a cross-point device of the crossbar circuit by selectively connecting a word line connected to the cross-point device to ground or the reference voltage.

### TECHNICAL FIELD

The implementations of the disclosure generally relate to crossbar circuits including resistive random-access memory devices and, more specifically, to bit-serial input schemes for crossbar circuits.

### BACKGROUND

A crossbar circuit may refer to a circuit structure with interconnecting electrically conductive lines sandwiching a memory element, such as a resistive switching material, at their intersections. The resistive switching material may include, for example, a memristor (also referred to as resistive random-access memory (RRAM or ReRAM)). Crossbar circuits may be used to implement in-memory computing applications, non-volatile solid-state memory, image processing applications, neural networks, etc.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one or more aspects, an apparatus including a crossbar circuit is provided. The apparatus may include a plurality of bit lines intersecting with a plurality of word lines; a plurality of cross-point devices; and a plurality of switches connected to the plurality of word lines. Each of the plurality of switches is selectively connected to ground or a reference voltage. each of the plurality of cross-point devices is connected to at least one of the plurality of word lines and at least one of the plurality of bit lines. Each of the plurality of cross-point devices includes a resistive random-access memory (RRAM) device.

In some embodiments, a first switch of the plurality of switches is connected to a first word line of the plurality of word lines, wherein the first switch is connected to the ground when a first bit of a digital input is applied to a first cross-point device, wherein the first cross-point device is connected to the first word line.

In some embodiments, the first switch is connected to the reference voltage when a second bit of the digital input is applied to the first cross-point device.

In some embodiments, the first bit of the digital input is a bit one, and the second bit of the digital input is a bit zero.

In some embodiments, a first terminal of a first RRAM device is connected to the first word line, wherein a second terminal of the first RRAM device is connected to a source terminal or a drain terminal of a transistor.

In some embodiments, the reference voltage corresponds to a read voltage applied to a bit line connected to the first cross-point device.

In some embodiments, the apparatus further includes a buffer that generates the reference voltage, wherein an output of the buffer is selectively connected to the plurality of switches.

In some embodiments, the buffer is a unity gain amplifier.

In some embodiments, the plurality of switches includes a plurality of multiplexers.

According to one or more aspects of the present disclosure, a method for performing in-memory computing using a crossbar circuit is provided. The method includes: providing a bit zero of a digital input to a first cross-point device by applying a reference voltage to a first word line,; and providing a bit one of the digital input to the first cross-point device by grounding the first word line.

In some aspects, the techniques described herein relate to a method, further including generating the reference voltage using a unity gain amplifier. The crossbar circuit includes a plurality of word lines intersecting with a plurality of bit lines. The first cross-point device is connected to the first word line and a first bit line. the reference voltage corresponds to a read voltage applied to the first bit line.

In some embodiments, applying the reference voltage to the first word line connected to the first cross-point device includes connecting an input of a switch to the reference voltage, wherein an output of the switch is connected to the first word line.

In some embodiments, grounding the first word line includes connecting the input of the switch to ground.

According to one or more aspects of the present disclosure, an apparatus including a crossbar circuit is provided. The apparatus includes a first plurality of bit lines and a second plurality of bit lines intersecting with a plurality of word lines; a first switch that selectively connects a first segment of a first word line of the plurality of word lines to ground; and a second switch that selectively connects a second segment of the first word line to ground; a first plurality of cross-point devices connecting to the first segment of the first word line and the first plurality of bit lines; and a second plurality of cross-point devices connecting to the second segment of the first word line and the second plurality of bit lines.

In some embodiments, each of the first plurality of cross-point devices and the second plurality of cross-point devices includes a resistive random-access memory (RRAM) device.

In some embodiments, the first segment of the first word line is floating when the first switch is off.

In some embodiments, the second segment of the first word line is floating when the second switch is off.

According to one or more aspects of the present disclosure, a method for performing in-memory computing using a crossbar circuit is provided. The method includes: providing a first bit to a first cross-point device in the crossbar circuit by connecting a first segment of a first word line to ground; and providing a second bit to the first cross-point device by setting the first segment of the first word line to float, wherein the crossbar circuit includes a plurality of word lines intersecting with a plurality of bit lines, wherein the first cross-point device is connected to the first word line and a first bit line of the plurality of bit lines.

In some embodiments, the method further includes providing a third bit to a second cross-point device by grounding a second segment of the first word line, wherein the second cross-point device is connected to the first word line and a second bit line of the plurality of bit lines.

In some embodiments, the method further includes providing a fourth bit to the second cross-point device by setting the second segment of the first word line to float.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding.

FIG. 1A is a schematic diagram illustrating an example crossbar circuit in accordance with some embodiments of the present disclosure.

FIGS. 1B and 1C are schematic diagrams illustrating example cross-point devices in accordance with some embodiments of the present disclosure.

FIGS. 2A and 2B are schematic diagrams illustrating example crossbar circuits in accordance with some embodiments of the present disclosure.

FIG. 3 is a flowchart illustrating an example method for performing in-memory computing using a crossbar circuit in accordance with one implementation of the present disclosure.

FIG. 4 is a flowchart illustrating an example method for performing in-memory computing using a crossbar circuit in accordance with another implementation of the present disclosure.

### DETAILED DESCRIPTION

Aspects of the disclosure provide bit-serial input schemes for crossbar circuits and methods for performing in-memory computing using the crossbar circuits. A crossbar circuit may include intersecting electrically conductive wires (e.g., word lines, bit lines, etc.) and cross-point devices arranged in one or more arrays (also referred to as the “crossbar arrays”) at the intersections of the electrically conductive wires. Each of the cross-point devices may be connected to a word line and a bit line.

A conventional crossbar circuit typically converts a digital input into an analog input and then applies the analog input to an array of cross-point devices. In such crossbar circuits, digital-to-analog converters (DACs) and drivers are used to generate an input analog voltage capable of driving the bit line current, resulting in additional energy and space consumption. Some existing crossbar circuits apply digital inputs to a crossbar array by applying the digital inputs to the gate of the transistors that provide access control to the cross-point devices. As the select lines share the input, this may lead to unnecessary power consumption and read disturbance on unused RRAM devices connected to the same select lines. In addition, the application of the input voltage on the transistor gate may cause variations of the voltage across a programmed RRAM device, leading to changes in the RRAM resistance and read disturbance.

According to the present disclosure, digital inputs may be provided to a crossbar circuit utilizing bit-serial input schemes. In one implementation, a digital input signal (e.g., a sequence of bits) may be provided to a cross-point device by selectively connecting a word line connected to the cross-point device to a reference voltage or ground. For example, a bit zero may be provided to the cross-point device by connecting the word line to a reference voltage corresponding to a read voltage applied to a bit line connected to the cross-point device. As another example, a bit one may be provided to the cross-point device by grounding the word line.

In another implementation, each word line in the crossbar circuit may include multiple segments. The digital input signal may be provided to a cross-point device by selectively grounding or floating the segment of the word line that is connected to the cross-point device. For example, a bit one may be provided to the cross-point device by grounding the segment of the word line. As another example, a bit zero may be provided to the cross-point device by floating the segment of the word line.

The bit-serial input schemes described herein may reduce the power consumption of the crossbar circuits and may avoid read disturbance caused by applying a relatively small switching voltage to selected cross-point devices.

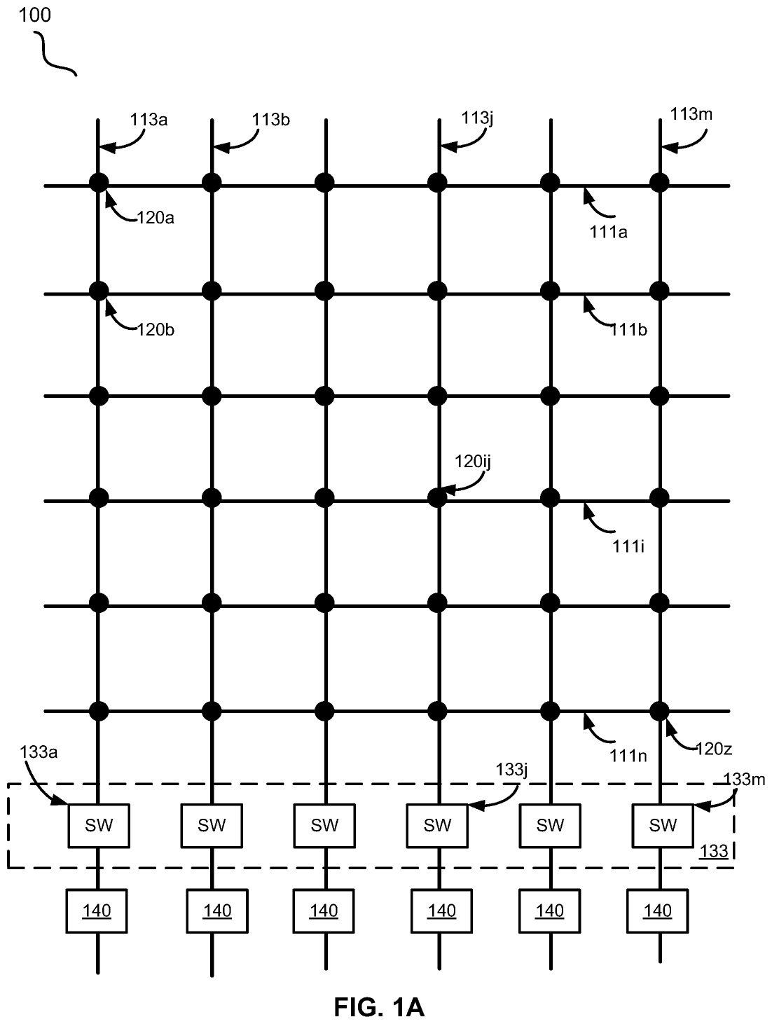

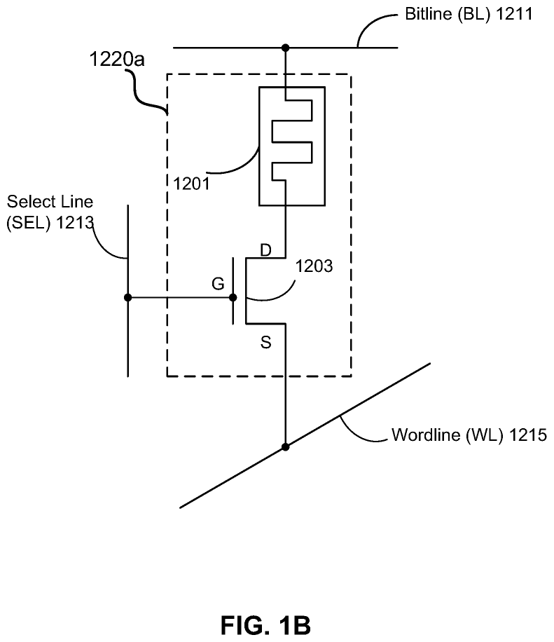

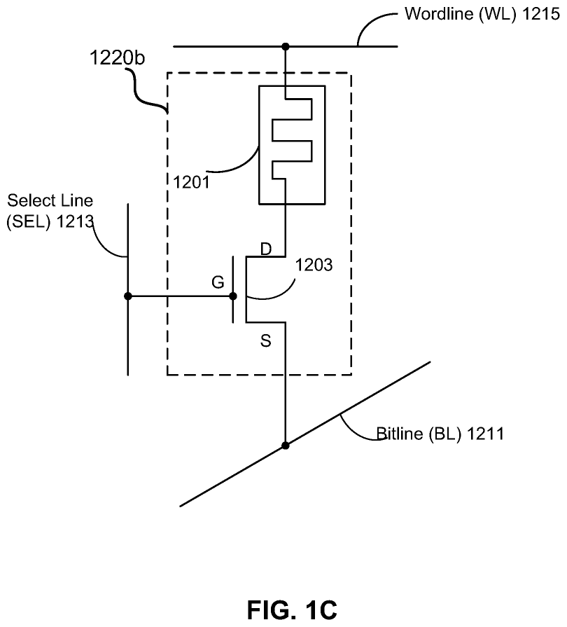

FIG. 1A is a schematic diagram illustrating an example 100 of a crossbar circuit in accordance with some embodiments of the present disclosure.

As shown, crossbar circuit 100 may include a plurality of interconnecting electrically conductive wires, such as one or more row wires 111a, 111b, . . . , 111i, . . . , 111n, and column wires 113a, 113b, . . . , 113j, . . . , 113m for an n-row by m-column crossbar array. The crossbar circuit 100 may further include cross-point devices 120a, 120b, . . . , 120ij, . . . , 120z, etc. Each of the cross-point devices may connect a row wire and a column wire. For example, the cross-point device 120ij may connect the row wire 111i and the column wire 113j. In some embodiments, crossbar circuit 100 may further include digital to analog converters (DAC, not shown), analog to digital converters (ADC, not shown), switches (not shown), and/or any other suitable circuit components for implementing a crossbar-based apparatus. The number of the column wires 113a-m and the number of the row wires 111a-n may or may not be the same.

Row wires 111a-n may include a first row wire 111a, a second row wire 111b, . . . , 111i, . . . ,and an n-th row wire 111n. Each of row wires 111a, . . . , 111n may be and/or include any suitable electrically conductive material. In some embodiments, each row wire 111a-n may be a metal wire.

Column wires 113a-m may include a first column wire 113a, a second column wire 113b, . . . , and an m-th column wire 113m. Each column wire 113a-m may be and/or include any suitable electrically conductive material. In some embodiments, each column wire 113a-m may be a metal wire.

Each cross-point device 120a-z may be and/or include any suitable device with tunable resistance, such as PCM (phase change memory) devices, floating gates, spintronic devices, resistive random-access memory (RRAM) devices, static random-access memory (SRAM) devices, ferroelectric devices, etc. In some embodiments, one or more cross-point devices 120a-z may include a cross-point device described in connection with FIGS. 1B-1C. In some embodiments, one or more cross-point devices 120a-z may be connected to one transistor to implement a 1TmR configuration.

Each column wire 113a-m may be connected to one or more column switches 133 (e.g., switches 133a, 133j, . . . , 133m). Each column switch 133a-m may include any suitable circuit structure that may control the current passes through bit lines 113a-m. In some embodiments, one or more of switches 133a-m may further provide fault protection, electrostatic discharge (ESD) protection, noise reduction, and/or any other suitable function for one or more portions of crossbar circuit 100.

Output sensor(s) 140 may include any suitable component for converting the current flowing through column wires 113a-m into digital outputs, such as one or more trans-impedance amplifiers (not shown), analog-to-digital converters (not shown), etc. In some embodiments, output sensor(s) 140 may further include one or more multiplexers (not shown).

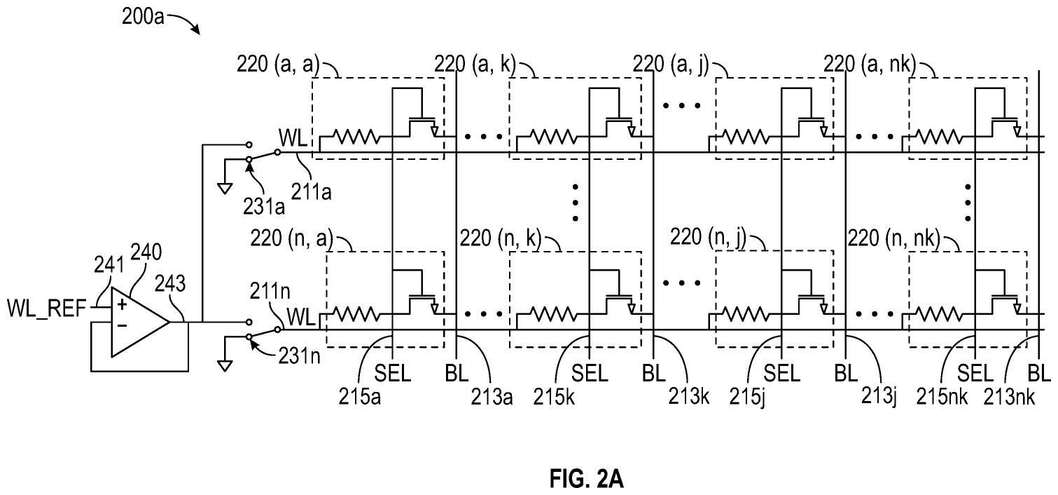

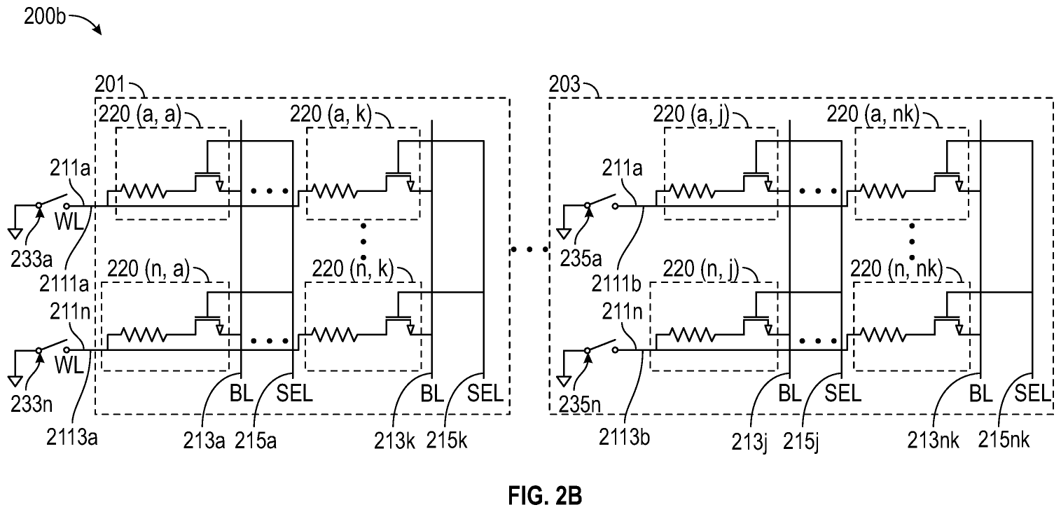

Crossbar circuit 100 may perform parallel weighted voltage multiplication and current summation. For example, an input voltage signal may be applied to one or more selected rows of crossbar circuit 100. The input signal may flow through the cross-point devices of the rows of the crossbar circuit 100. The conductance of the cross-point device may be programmed to a specific value (also referred to as a “weight”). By Ohm's law, the input voltage multiplies the cross-point conductance and generates a current from the cross-point device. By Kirchhoff's law, the summation of the current passing the devices on each column generates the current as the output signal, which may be read from the columns (e.g., outputs of the ADCs). According to Ohm's law and Kirchhoff's current law, the input-output relationship of the crossbar array can be represented as I=VG, wherein I represents the output signal matrix as current; V represents the input signal matrix as voltage; and G represents the conductance matrix of the cross-point devices. As such, the input signal is weighted at each of the cross-point devices by its conductance according to Ohm's law. The weighted current is output via each column wire and may be accumulated according to Kirchhoff's current law. In some embodiments, the input signal may be provided to the crossbar circuit 100 utilizing one or more bit-serial input schemes described in connection with FIGS. 2A-5.

Crossbar circuit 100 may be configured to perform vector-matrix multiplication (VMM). A VMM operation may be represented as Y=XA, wherein each of Y, X, A represents a respective matrix. More particularly, for example, input vector X may be mapped to the input voltage V of crossbar circuit 100. Matrix A may be mapped to conductance values G. The output current I may be read and mapped back to output results Y. In some embodiments, crossbar circuit 100 may be configured to implement a portion of a neural network by performing VMMs.

FIGS. 1B and 1C are schematic diagrams illustrating example cross-point devices 1220a and 1220b in accordance with some embodiments of the present disclosure. Each cross-point device 1220a and 1220b may be referred to as a 1-transistor-1-resistor (1T1R) configuration.

As shown in FIGS. 1B and 1C, a cross-point device 1220a-b may include an RRAM device 1201 and a transistor 1203 that are connected in series. A transistor may include three terminals that may be marked as gate (G), source(S), and drain (D), respectively. Referring to

FIG. 1B, a first terminal of RRAM device 1201 may be connected to the drain of transistor 1203. A second terminal of RRAM device 1201 may be connected to a bit line 1211. The source of the transistor 1203 may be connected to a word line 1215. The gate of transistor 1203 may be connected to a select line 1213.

As shown in FIG. 1C, the second terminal of RRAM device 1201 may be connected to a word line 1215, and the source of the transistor 1203 may be connected to a bit line 1211 in some embodiments. Word line 1215 may correspond to a row wire 111a-n of FIG. 1A. Bit line 1211 may correspond to a column wire 123a-m of FIG. 1A.

Transistor 1203 may function as a selector as well as a current controller and may set the current compliance to RRAM device 1201 during programming. The gate voltage on transistor 1203 can set current compliances to cross-point device 1220a-b during programming and can thus control the conductance and analog behavior of cross-point device 1220a-b. For example, when cross-point device 1220a-b is set from a high-resistance state to a low-resistance state, a set signal (e.g., a voltage signal, a current signal) may be provided via bit line (BL) 1211 (or word line (WL) 1215). Another voltage, also referred to as a select voltage or gate voltage, may be applied via select line (SEL) 1213 to the transistor gate to open the gate and set the current compliance, while word line (WL) 1215 (or bit line (BL)) may be grounded. When cross-point device 1220a-b is reset from the low-resistance state to the high-resistance state, a gate voltage may be applied to the gate of transistor 1203 via select line 1213 to open the transistor gate. Meanwhile, a reset signal may be sent to RRAM device 1201 via word line 1215 (or bit line 1211), while bit line 1211 or (word line 1215) may be grounded.

FIGS. 2A and 2B are schematic diagrams illustrating example crossbar circuits 200a and 200b in accordance with some embodiments of the present disclosure. Each crossbar circuit 200a and 200b is an example of crossbar circuit 100 of FIG. 1A in greater detail.

Referring to FIG. 2A, crossbar circuit 200a may include word line (WL) 211a, . . . , 211n, bit lines (BL) 213a, . . . , 213k, . . . , 213j, . . . , 213nk, and select lines (SEL) 215a, . . . , 215k, . . . , 215j, . . . , 215nk, which are intersecting conductive wires. Crossbar circuit 200a may further include cross-point devices 220(a, a), . . . , 220(a, k), . . . , 220(a, j), . . . , 220(a, nk), . . . , 220(n, a), . . . , 220(n, k), . . . , 220(n, j), . . . , 220(n, nk) (collectively referred to as cross-point devices 220). As shown, each cross-point device 220 may be connected to a word line 211a-n, a bit line 213a-nk, and a select line 215a-nk. In some embodiments, word lines 211a-n and bit lines 213a-m may be the same as row lines 111a-n and column lines 113a-m of FIG. 1A, respectively. In some embodiments, word lines 211a-n and bit lines 213a-m may be the same as column lines 113a-m and row lines 111a-n of FIG. 1A, respectively.

In some embodiments, each cross-point device 220 may include a transistor and an RRAM device connected in series (e.g., a 1T1R configuration as described in connection with FIGS. 1B-1C).

Crossbar circuit 200a may further include a plurality of switches 231a, . . . , 231n. Each switch 231a-n may selectively connect one of a plurality of input lines to a single common output line. As shown in FIG. 2A, a first input line of a switch 231a-n may be connected to the output 243 of a buffer 240. A second input line of the switch 231a-n may be connected to ground. The output line of the switch 231a-n may be connected to a respective word line and may be selectively connected to one of the input lines of the switch. As such, each switch 231a, . . . , 231n may be connected to a respective word line 211a, . . . , 211n and may selectively connect the respective word line to one of a plurality of inputs (e.g., ground, the reference voltage, etc.). Switch 231a-n may be implemented using any suitable circuitry that may perform the switching functions described herein. In some embodiments, one or more switches 231a-n may be a multiplexer.

Performing in-memory computing using crossbar circuit 200a may involve selecting one or more cross-point devices 220 by applying a suitable select voltage to one or more select lines 215a-n connected to the cross-point devices to be selected. The conductance of the RRAM devices in the selected cross-point devices may then be programmed to suitable values (e.g., conductance values corresponding to a weight matrix W).

A digital input signal (e.g., a binary input signal) may be applied to the selected cross-point device(s) via the word line(s) connected to the selected RRAM device(s) and cross-point device(s). The binary input signal may include one or more bits (e.g., a sequence of bits). Each of the bits may be a bit “0” or a bit “1”. The bits may be applied to the selected RRAM device(s) in series (e.g., one bit at a time). For example, a bit “1” may be provided to a selected cross-point device (e.g., cross-point device 220(a, a)) as input by connecting the word line connected to the selected cross-point device (e.g., word line 211a) to ground (e.g., via switch 231a). As another example, a bit “0” may be provided to the selected cross-point device (e.g., cross-point device 220(a, a)) as input by connecting the word line connected to the selected cross-point device (e.g., word line 211a) to a reference voltage. As such, a bit “1” is provided to the selected cross-point device as a current flows through the cell, and a bit “0” is provided to the selected cross-point device as no current passes through the cross-point device. The reference voltage may correspond to the read voltage applied to the bit line connected to the selected cross-point device (e.g., bit line 215a). That is, the reference voltage may be the same or substantially the same as the read voltage. As such, no current or substantially no current may flow through the RRAM device in the selected cross-point device in response to the application of the input binary signal and the read voltage. The read voltage is typically much lower than the select voltage applied to the gate of the transistor. For example, the read voltage is typically in the range of 0.1v to 0.3v, while the select voltage is typically 0.6V or higher since it is required to turn on the gate of the transistor. The power consumed during the switching of an RRAM device may be equal to CV²f, where C is the capacitance, V is the switching voltage, and f is the switching frequency. As a result, the bit-serial input scheme described herein may reduce power consumption by using a lower switching voltage.

Crossbar circuit 200a may further include a buffer 240 for producing the reference voltage. The buffer 240 may be a unity gain amplifier in some embodiments. The output of buffer 240 may be selectively connected to one or more word lines 211a-n via switches 231a-n. The input 241 of the buffer 240 may be connected to a word line reference voltage WL_REF. WL_REF may be the same or substantially the same as the read voltage applied to the bit line connected to the selected cross-point device. In some embodiments, the word line reference voltage WL_REF may be produced by a DAC (not shown), a bandgap circuit (not shown), and/or any other suitable circuitry that may produce the reference voltage. As WL_REF is lower than the voltage that may cause read disturbance, the bit-serial input scheme does not cause read disturbance in the crossbar circuit 200a.

Referring to FIG. 2B, the cross-point devices in a crossbar circuit may be divided into multiple logical groups (also referred to as “banks”). Each logical group or bank may include an array of cross-point devices connected to one or more bit lines. For example, a first bank 201 of crossbar circuit 200b may include the cross-point devices that are connected to bit lines 213a, . . . , 213k and word lines 211a, . . . , 211n, such as cross-point devices 220(a, a), . . . , 220(a, k), . . . , 220(n, a), . . . , 220(n, k). A second bank 203 may include the cross-point devices that are connected to bit lines 213j, . . . , 213nk and word lines 211a-n, such as cross-point devices 220(a, j), . . . , 220(a, nk), . . . , 220(n, j), . . . , 220(n, nk). Each bank may include an array of any suitable number of cross-point devices connected to a suitable number of bit lines (e.g., 8 bit lines, 16 bit lines, 32 bit lines, etc.).

While two banks are shown in FIG. 2B for simplicity, this is merely illustrative. A crossbar circuit as described herein may be divided into any suitable number of banks to achieve desirable processing granularity, speed, and/or chip density.

As shown, each word line 211a-n may include multiple segments (e.g., segments 2111a, . . . ,2111b of word line 211a, segments 2113a, . . . , 2113b of word line 211n, etc.). Each of the segments may be located at a respective bank. For example, a first segment 2111a and a second segment 2111b of word line 211a may be located in first bank 201 and second bank 203, respectively. The first segment 2111a of the word line 211a is connected to cross-point devices 220(a, a), . . . , 220(a, k). The second segment 2111b of the first word line 211a is connected to cross-point devices 220(a, j), . . . , and 220(a, nk).

Each word line 211a-n may be connected to a switch 233a, . . . , 233n (also referred to as the “first plurality of switches”) to provide input signals to the cross-point devices in first bank 201. The second segment of a word line 211a-n may further be connected to a switch 235a, . . . , 235n (also referred to as the “second plurality of switches”) to provide input signals to the cross-point devices in second bank 203. Each switch 233a, . . . , 233n, 235a, . . . , 235n may be selectively connected to ground. As such, a segment of a word line 211a-n may be grounded or floating via a respective switch 233a, . . . , 233n, 235a, . . . , 235n. For example, the first segment 2111a of the first word line 211a may be connected to switch 233 and may be connected to ground via switch 233a. When switch 233a is on, the first segment 2111a of the first word line 211a is grounded. When switch 233a is off, the first segment 2111a of the first word line 211a is floating. As another example, the second segment 2111b of the first word line 211a may be connected to switch 235a and may be connected to ground via switch 235a. When switch 235a is on, the second segment 2111b of the first word line 211a is grounded. When switch 235a is off, the second segment 2111b of the first word line 211a is floating.

As described above, one or more cross-point devices in crossbar circuit 200b may be selected for programming and/or in-memory computing. A digital input signal (e.g., a binary input) may be applied to the selected cross-point device(s) via the segment(s) of the word line(s) connected to the selected cross-point device(s). The digital input signal may include one or more bits (e.g., a sequence of bits) that may be applied to the selected cross-point device(s) in series (e.g., one bit at a time). For example, a bit “0” may be provided to a first cross-point device 220(a, a) as input by connecting the first segment 2111a of word line 211a to ground via switch 233a. In some embodiments, switch 235a may be open while switch 233a is closed to provide the bit “1” to the first segment 2111a of the word line 211a. Similarly, a bit “1” may be provided to a second cross-point device 220(a, j) as input by connecting the second segment 2111b of the word line 211a. As another example, a bit “0” may be provided to the first cross-point device 220(a, a) by setting the first segment 2111a of word line 211a to float. For example, switch 233a may be off and not connected to the ground. Similarly, a bit “0” may be provided to the second cross-point device 220(a, j) as input by setting the second segment 2111b of word line 211a to float (e.g., by disconnecting switch 235a from the ground).

The crossbar circuit architecture as described in FIG. 2B does not accumulate word line current during in-memory computing operations, leading to a significant reduction in IR drop and enabling the use of the minimum metal width for routing. This may reduce parasitic capacitance loading on the WL and minimize the errors in VMM operations caused by the IR drop. In addition, the bit lines are effectively decoupled utilizing the individual bank control scheme, minimizing the sneak current flowing from one bit line to another bit line. This may enhance the accuracy of the VMM operations performed by the crossbar circuit 200b. The scheme described in connection with FIG. 2B may further simplify the system's configuration as it does not require a buffer for generating reference voltages.

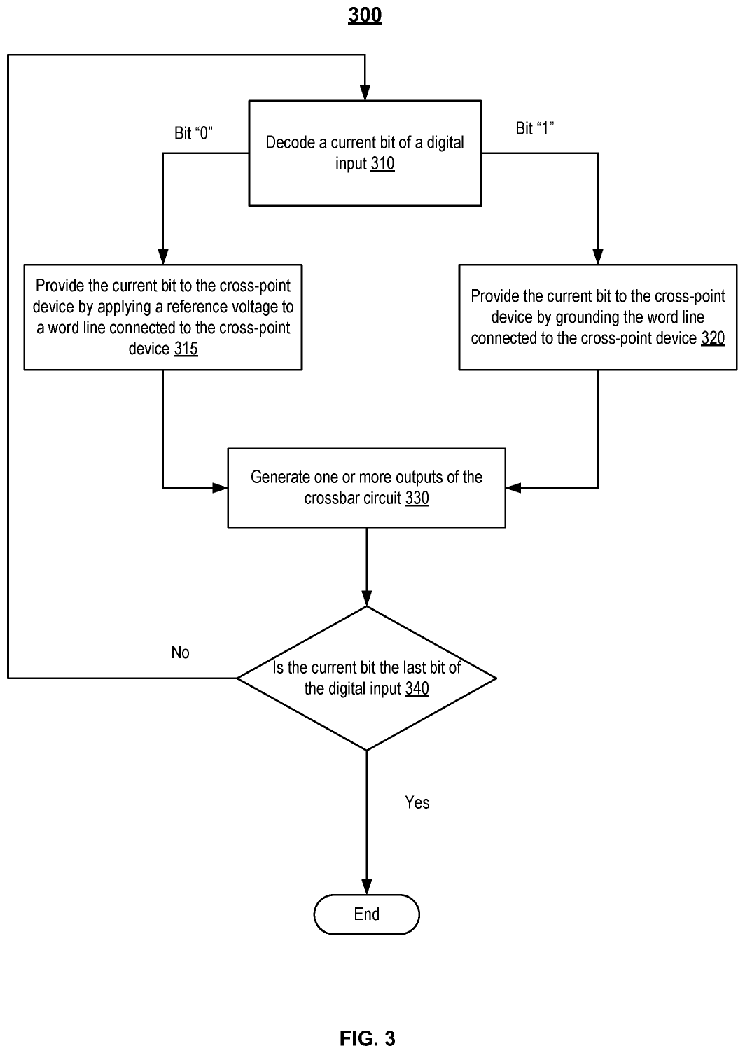

FIG. 3 is a flowchart illustrating an example method for performing in-memory computing using a crossbar circuit in accordance with some embodiments of the present disclosure. The crossbar circuit may be, for example, the crossbar circuit 200a of FIG. 2A.

At block 310, a current bit of a digital input may be decoded. The current may be a bit zero or a bit one. The digital input may include a sequence of bits. In some embodiments, the digital input may represent an input vector X for performing a VMM operation Y=XA.

In some embodiments in which the current bit of the digital input is a bit zero, process 300 may proceed to block 315 and may provide the current bit to a cross-point device of the crossbar circuit by applying a reference voltage to a word line (e.g., word line 211a of FIG. 2A) connected to the cross-point device (e.g., cross-point device 220(a, a) of FIG. 2A). The reference voltage may correspond to a read voltage applied to the bit line (e.g., bit line 213a of FIG. 2A) connected to the cross-point device. For example, the reference voltage may be the same or approximately the same as the read voltage applied to the bit line. The reference voltage may be generated by a buffer (e.g., buffer 240 of FIG. 2A). In some embodiments, the reference voltage may be applied on the word line by connecting the word line to the reference voltage via a switch (e.g., switch 231a of FIG. 2A).

In some embodiments in which the current bit of the digital input is a bit one, process 300 may proceed to block 320 and may provide the current bit to the cross-point device by grounding the word line connected to the cross-point device. For example, the input of the switch (e.g., switch 231a of FIG. 2A) connected to the word line may be switched to the ground.

At block 330, one or more outputs of the crossbar circuit may be generated. For example, an output sensor connected to the bit line (e.g., an output sensor 140 of FIG. 1) may be turned on and may generate one or more digital outputs representative of the current flowing through the bit line.

At block 340, a determination may be made as to whether the current bit is the last bit of the digital input. If the current bit is the last bit of the digital input, process 300 may conclude. Alternatively, process 300 may loop back to 310 and may decode the next bit of the digital input.

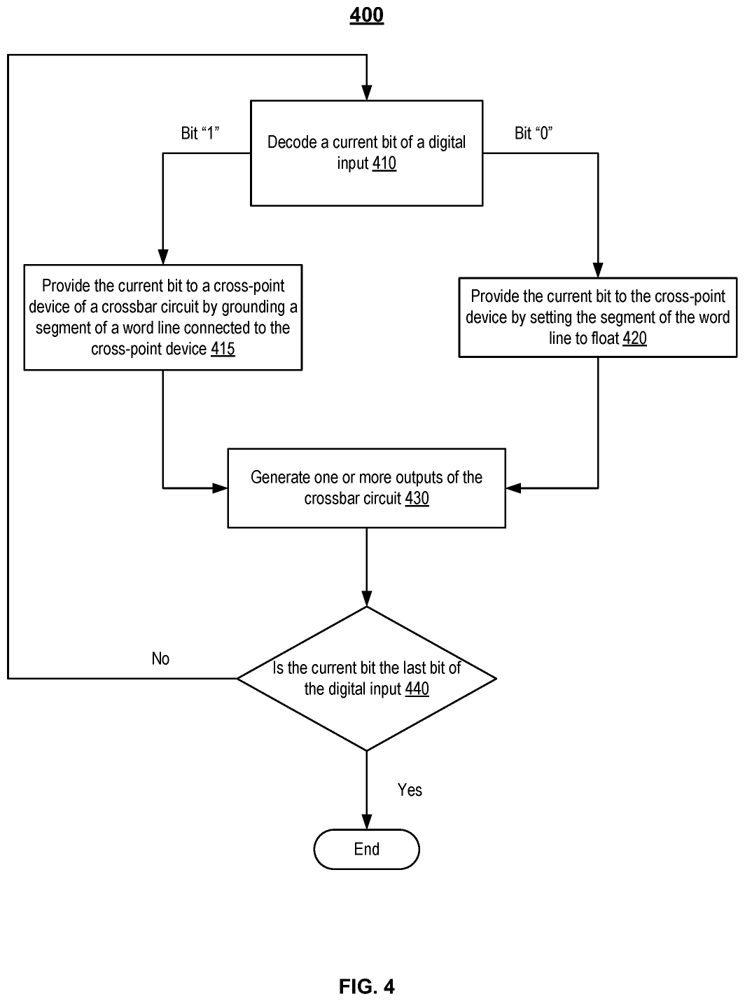

FIG. 4 is a flowchart illustrating an example method for performing in-memory computing using a crossbar circuit in accordance with some embodiments of the present disclosure. The crossbar circuit comprises a plurality of word lines intersecting with a plurality of bit lines and arrays of cross-point devices. The crossbar circuit may be, for example, the crossbar circuit 200b of FIG. 2B.

At block 410, a current bit of a digital input may be decoded. The current bit may be a bit zero or a bit one. The digital input may include a sequence of bits. In some embodiments, the digital input may represent an input vector X for performing a VMM operation Y=XA.

In some embodiments in which the current bit of the digital signal is a bit one, process 400 may proceed to block 415 and may provide the current bit to a cross-point device by grounding a segment of the word line connected to the cross-point device. For example, to provide a bit one (also referred to as the “first bit”) to a first cross-point device 220(a, a) of FIG. 2B, a first segment 2111a of the first word line 211a may be connected to ground via a first switch connected to the first segment of the word line (e.g., switch 233a of FIG. 2B). As another example, to provide a bit one (also referred to as the “third bit”) to a second cross-point device 220(a, j) of FIG. 2B, a second segment 2111b of the word line may be connected to the ground via a second switch connected to the second segment of the word line (e.g., switch 235a of FIG. 2B).

In some embodiments in which the current bit of the digital signal is a bit zero, process 400 may proceed to block 420 and may provide the current bit to the cross-point device by setting the segment of the word line to float. For example, to provide a bit zero (also referred to as the “second bit”) to the first cross-point device 220(a, a) of FIG. 2B, the first segment 2111a of the first word line 211a may be set to float by disconnecting the first switch 233a from the ground (e.g., switched off). As another example, to provide a bit zero (also referred to as the “fourth bit”) to the second cross-point device 220(a, j) of FIG. 2B, the second segment 2111b of the first word line 211a may be set to float by disconnecting the second switch 235a from the ground (e.g., switched off).

At block 430, one or more outputs of the crossbar circuit may be generated. For example, an output sensor connected to the bit line (e.g., an output sensor 140 of FIG. 1) may be turned on and may generate one or more digital outputs representative of the current flowing through the bit line.

At block 440, a determination may be made as to whether the current bit is the last bit of the digital input. If the current bit is the last bit of the digital input, process 400 may conclude. Alternatively, process 400 may loop back to 410 and the next bit of the digital input may be decoded.

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events.

The terms “approximately,” “about,” and “substantially” as used herein may mean within a range of normal tolerance in the art, such as within 2 standard deviations of the mean, within ±20% of a target dimension in some embodiments, within ±10% of a target dimension in some embodiments, within ±5% of a target dimension in some embodiments, within ±2% of a target dimension in some embodiments, within ±1% of a target dimension in some embodiments, and yet within ±0.1% of a target dimension in some embodiments. The terms “approximately” and “about” may include the target dimension. Unless specifically stated or obvious from context, all numerical values described herein are modified by the term “about.”

As used herein, a range includes all the values within the range. For example, a range of 1 to 10 may include any number, combination of numbers, sub-range from the numbers of 1, 2, 3, 4, 5, 6, 7, 8, 9, and 10 and fractions thereof.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. An apparatus, comprising:
a plurality of bit lines intersecting with a plurality of word lines;
a plurality of cross-point devices, wherein each of the plurality of cross-point devices is connected to at least one of the plurality of word lines and at least one of the plurality of bit lines, and wherein each of the plurality of cross-point devices comprises a resistive random-access memory (RRAM) device; and
a plurality of switches connected to the plurality of word lines, wherein each of the plurality of switches is selectively connected to ground or a reference voltage.

2. The apparatus of claim 1, wherein a first switch of the plurality of switches is connected to a first word line of the plurality of word lines, wherein the first switch is connected to the ground when a first bit of a digital input is applied to a first cross-point device, wherein the first cross-point device is connected to the first word line.

3. The apparatus of claim 2, wherein the first switch is connected to the reference voltage when a second bit of the digital input is applied to the first cross-point device.

4. The apparatus of claim 3, wherein the first bit of the digital input is a bit one, and wherein the second bit of the digital input is a bit zero.

5. The apparatus of claim 2, wherein a first terminal of a first RRAM device is connected to the first word line, and wherein a second terminal of the first RRAM device is connected to a source terminal or a drain terminal of a transistor.

6. The apparatus of claim 2, wherein the reference voltage corresponds to a read voltage applied to a bit line connected to the first cross-point device.

7. The apparatus of claim 1, further comprising a buffer that generates the reference voltage, wherein an output of the buffer is selectively connected to the plurality of switches.

8. The apparatus of claim 7, wherein the buffer is a unity gain amplifier.

9. The apparatus of claim 1, wherein the plurality of switches comprises a plurality of multiplexers.

10. A method for performing in-memory computing using a crossbar circuit, comprising:
providing a bit zero of a digital input to a first cross-point device by applying a reference voltage to a first word line, wherein the crossbar circuit comprises a plurality of word lines intersecting with a plurality of bit lines, wherein the first cross-point device is connected to the first word line and a first bit line, wherein the reference voltage corresponds to a read voltage applied to the first bit line; and
providing a bit one of the digital input to the first cross-point device by grounding the first word line.

11. The method of claim 10, further comprising generating the reference voltage using a unity gain amplifier.

12. The method of claim 10, wherein applying the reference voltage to the first word line connected to the first cross-point device comprises connecting an input of a switch to the reference voltage, wherein an output of the switch is connected to the first word line.

13. The method of claim 12, wherein grounding the first word line comprises connecting the input of the switch to ground.

14. An apparatus, comprising:
a first plurality of bit lines and a second plurality of bit lines intersecting with a plurality of word lines;
a first switch that selectively connects a first segment of a first word line of the plurality of word lines to ground;
a second switch that selectively connects a second segment of the first word line to ground;
a first plurality of cross-point devices connecting to the first segment of the first word line and the first plurality of bit lines; and
a second plurality of cross-point devices connecting to the second segment of the first word line and the second plurality of bit lines.

15. The apparatus of claim 14, wherein each of the first plurality of cross-point devices and the second plurality of cross-point devices comprises a resistive random-access memory (RRAM) device.

16. The apparatus of claim 14, wherein the first segment of the first word line is floating when the first switch is off.

17. The apparatus of claim 16, wherein the second segment of the first word line is floating when the second switch is off.

18. A method for performing in-memory computing using a crossbar circuit, comprising:
providing a first bit to a first cross-point device in the crossbar circuit by connecting a first segment of a first word line to ground; and
providing a second bit to the first cross-point device by setting the first segment of the first word line to float, wherein the crossbar circuit comprises a plurality of word lines intersecting with a plurality of bit lines, wherein the first cross-point device is connected to the first word line and a first bit line of the plurality of bit lines.

19. The method of claim 18, further comprising providing a third bit to a second cross-point device by grounding a second segment of the first word line, wherein the second cross-point device is connected to the first word line and a second bit line of the plurality of bit lines.

20. The method of claim 19, further comprising providing a fourth bit to the second cross-point device by setting the second segment of the first word line to float.
